(19) United States
(12) Patent Application Publication
(10) Pub. No.: US 2015/0029674 A1
(43) Pub. Date: Jan. 29, 2015

(54) PRINTED CIRCUIT BOARD SET HAVING HIGH-EFFICIENCY HEAT DISSIPATION

(71) Applicant: JITBOUNDARY UNITED PRODUCTION INC., New Taipei City (TW)

(72) Inventors: Po-Wen KO, New Taipei City (TW); Chin-Chia CHANG, New Taipei City (TW)

(21) Appl. No.: 14/339,935

(22) Filed: Jul. 24, 2014

(30) Foreign Application Priority Data
Jul. 26, 2013 (TW) 102126864

(51) Int. Cl. H05K 1/02

(52) U.S. Cl. CPC H05K 1/0206; H05K 2201/06
USPC 361/720

(57) ABSTRACT

A printed circuit board set having high-efficiency heat dissipation includes a printed circuit board (PCB) and a heat dissipating device. The PCB has multiple electronic elements, at least one heat dissipating hole, and at least one thermally conductive material. The electronic elements are disposed on the top surface of the PCB. Each of the at least one heat dissipating hole is formed through the top and bottom surfaces of the PCB and aligns with one of the electronic elements. Each of the at least one thermally conductive material is disposed in the corresponding heat dissipating hole and in contact with the corresponding electronic element. The heat dissipating device is attached to the bottom surface of the PCB and in contact with the at least one thermally conductive material. With a high thermal conductivity, the at least one thermally conductive material rapidly transfers the waste heat produced by the PCB in operation to the heat dissipating device for heat dissipation.

### BACKGROUND OF THE INVENTION

1. Field of Invention

The invention relates to a printed circuit board set having high-efficiency heat dissipation, and in particular, to a printed circuit board set that modifies local thermal conductivity of a printed circuit board to enhance heat dissipation.

2. Description of the Prior Art

In the contemporary society, electronic devices have become an indispensable part of life. People keep pursuing small but highly efficient electronic devices. However, as the circuit systems become smaller and faster, there comes the problem of heat dissipation. This factor has to be taken into account in circuit designs.

An electronic device generally has a printed circuit board on which electronic elements are distributed to have complete functions. Some of the electronic elements, such as processors, transistors, resistors, capacitors, and light-emitting diodes (LED's), can generate a significant amount of waste heat during the operation of the electronic device. As the waste heat accumulates, the printed circuit board and the electronic elements thereon have high temperatures that result in malfunction of the electronic elements or even failure of the entire electronic device. What is worse is that the printed circuit board and the electronic elements thereon may have short circuits and burn out. Therefore, how to dissipate the accumulated waste heat is an important issue in modern electronic device designs.

As shown in FIG. 7, the conventional heat dissipating printed circuit board set has a printed circuit board 40 and a metal heat dissipating base 50. The bottom surface of the printed circuit board 40 is attached to the top surface of the heat dissipating base 50. The top surface of the printed circuit board 40 has a plurality of electronic elements 41. The bottom surface of the heat dissipating base 50 is formed with a plurality of heat dissipating fins 51 to increase the heat dissipating area. During the operation of the printed circuit board 40, the waste heat produced by the electronic elements 41 is transferred to the top surface of the printed circuit board 40, then to the bottom surface of the printed circuit board 40, and finally to the heat dissipating base 50 in contact with the bottom surface of the printed circuit board 40. The heat is then dissipated by the heat dissipating fins 51.

Nevertheless, to increase the efficiency and reliability of the printed circuit board, most of the conventional printed circuit boards are made of materials with good insulation. A commonly used material that has good insulation and low cost is the glass fabric epoxide resin laminates (GE) and/or paper-based benzoic acid laminates (PP). However, these two materials do not have good thermal conductivity. Even when the printed circuit board is in direct contact with a heat dissipating base having a good thermal conductivity, the electronic elements thereon still rely on the printed circuit board to transfer the waste heat to the heat dissipating base. The low thermal conductivity of the printed circuit board reduces the overall heat dissipation efficiency. In the end, the heat dissipation speed cannot catch up with the heat production speed, resulting in waste heat accumulation and temperature rise.

### SUMMARY OF THE INVENTION

In view of the foregoing problem of inefficient heat dissipation due to the low thermal conductivity of the printed circuit board material, an objective of the invention is to provide a printed circuit board (PCB) set having high-efficiency heat dissipation.

The disclosed PCB set includes:

a PCB, which has a plurality of electronic elements, at least one heat-dissipating hole, and at least one thermally conductive material; wherein the electronic elements are disposed on a top surface of the PCB, each of the at least one heat dissipating hole is formed through the top and bottom surfaces of the PCB and aligns with one of the electronic elements, and each of the at least one thermally conductive material is accommodated in the corresponding heat dissipating hole and in contact with the corresponding electronic element; and

a heat dissipating device, which is attached to the bottom surface of the PCB and in contact with the at least one thermally conductive material.

The PCB set improves the thermal conductivity of the part between the PCB and the electronic elements. The thermally conductive material replaces the PCB, which has inferior thermal conductivity, for contact with the electronic elements and the heat dissipating device. Therefore, waste heat produced by the electronic elements during their operations is transferred by the thermally conductive materials to the heat dissipating device for heat dissipation.

### BRIEF DESCRIPTION OF THE DRAWINGS

FIG. 1 is an exploded view of a PCB set according to a first embodiment of the invention, shown without the thermally conductive material;

FIG. 2 is a cross-sectional view of the PCB set according to the first embodiment of the invention, shown without the thermally conductive material;

FIG. 3 is a cross-sectional view of the PCB set according to the first embodiment of the invention, shown without the thermally conductive material and combined with a heat dissipating device;

FIG. 4 is a cross-sectional view of the PCB set combined with a heat dissipating device according to the first embodiment of the invention;

FIG. 5 is a perspective view of the first embodiment of the invention;

FIG. 6 is a cross-sectional view of the PCB set according to a second embodiment of the invention, shown combined with a heat dissipating device; and

FIG. 7 is a perspective view of a conventional heat dissipating PCB set.

### DETAILED DESCRIPTION OF THE PREFERRED EMBODIMENTS

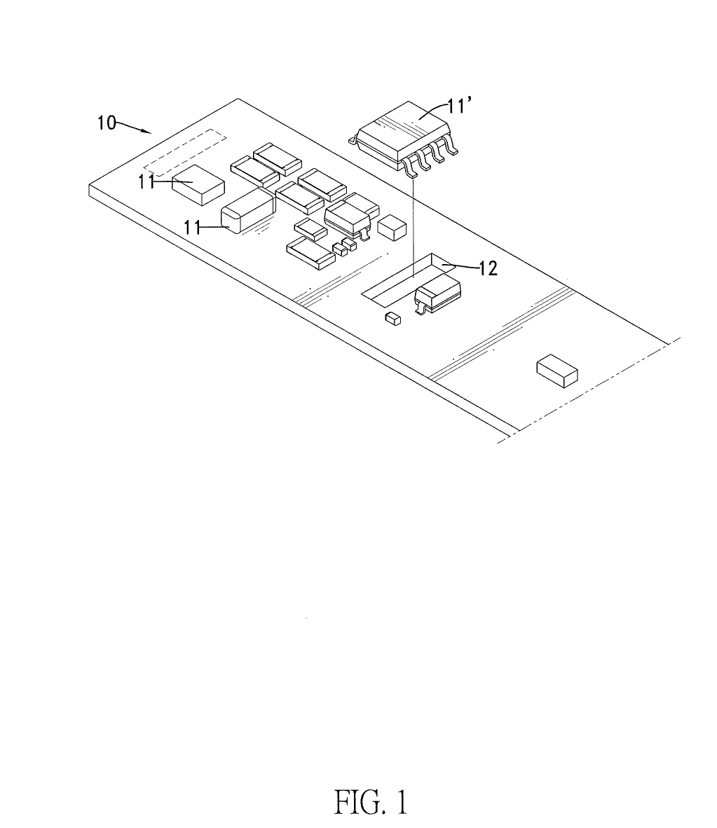

FIG. 1 shows a first embodiment of a PCB set having high-efficiency heat dissipation, which includes a PCB 10, a heat dissipating device 20, and at least one thermally conductive material 30. In this embodiment, only one thermally conductive material 30 is drawn for ease of illustration.

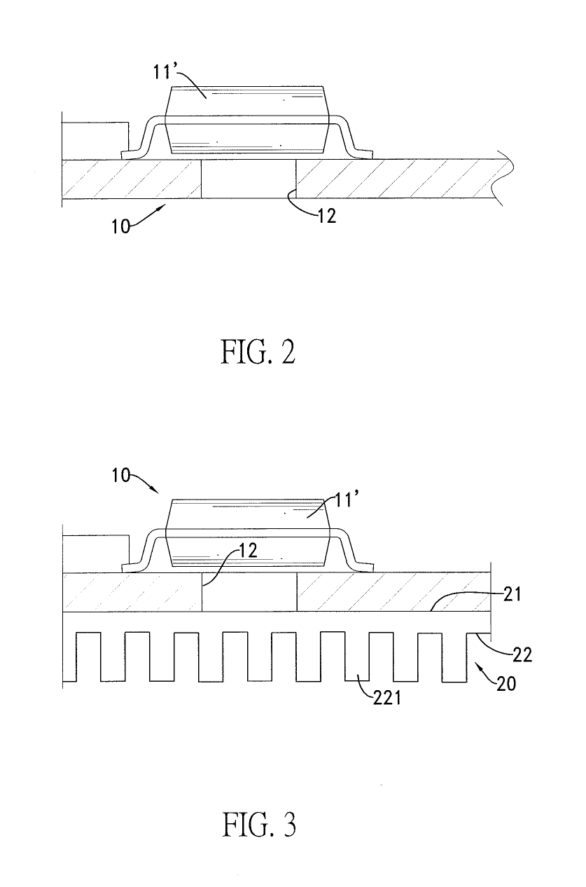

With reference to FIG. 2, the PCB 10 has multiple electronic elements 11 and at least one heat dissipating hole 12. The electronic elements 11 are disposed on a top surface of the PCB 10, such that the PCB 10 is functional and operable. Each of the at least one heat dissipating hole 12 is formed through the top surface and a bottom surface of the PCB 10, and aligns with an electronic element 11′ that is likely to produce a lot of heat during its operation. The electronic elements 11, 11′ can be processors, transistors, resistors, capacitors, or LED's.

With reference to FIG. 3, the heat dissipating device 20 has a thermally conductive surface 21 and a heat dissipating surface 22. The thermally conductive surface 21 is attached to the bottom surface of the PCB 10. The heat dissipating surface 22 extends downward to form a plurality of heat dissipating fins 221 to increase the heat dissipating area. The heat dissipating device 20 is made of a metal with high thermal conductivity.

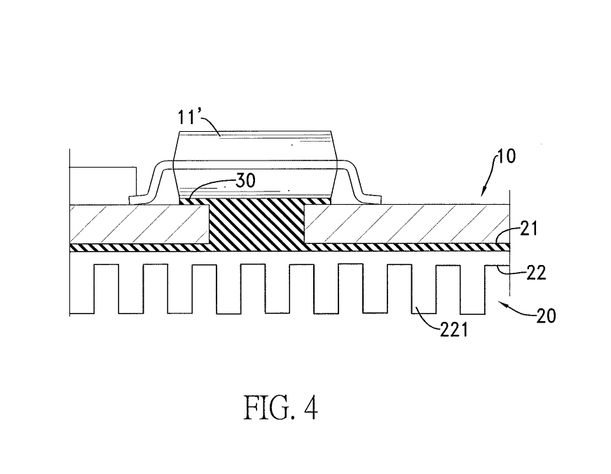

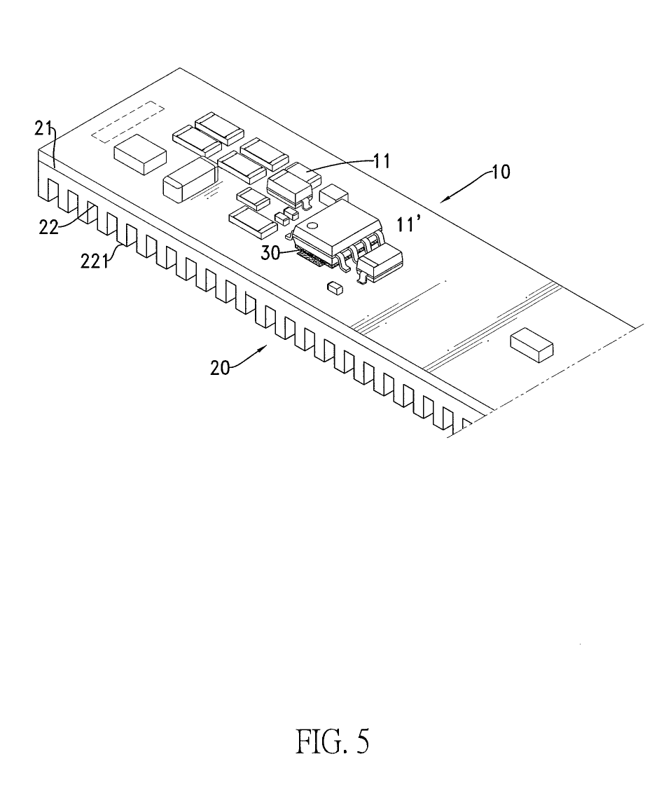

With reference to FIG. 4, the thermally conductive material 30 has high thermal conductivity and is accommodated in the heat dissipating hole 12 of the PCB 10 to be in contact with the heat-generating electronic element 11′. Specifically, the thermally conductive material 30 is accommodated in the at least one heat dissipating hole 12 in its liquid state by pouring. After the PCB 10 is combined with the heat dissipating device 20, the liquid-state thermally conductive material 30 is poured into and fills the heat dissipating hole 12, thereby in direct contact with the thermally conductive surface 21 of the heat dissipating device 20. The thermally conductive material 30 is poured until it overflows. The overflowing thermally conductive material 30 fills the gap between the bottom surface of the heat-generating electronic element 11′ and the top surface of the PCB 10. After curing, the thermally conductive material 30 contacts the heat-generating electronic element 11′ and is fixed inside the heat dissipating hole 12. Both ends of the cured thermally conductive material 30 are in contact with the thermally conductive surface 21 of the heat dissipating device 20 and the heat-generating electronic element 11′ on the top surface of the PCB 10, respectively, to transfer heat. Moreover, the thermally conductive material 30 is preferably an electrical insulator, such as thermally conductive silicone, epoxy resin, or rubber.

With the above-mentioned structure, the invention improves the thermal conductivity of the part between the PCB and the electronic elements. That is, the thermally conductive material 30 having good thermal conductivity replaces the PCB 10 having inferior thermal conductivity for contact with the heat generating electronic elements 11′ and the heat dissipating device 20. Therefore, waste heat produced by the electronic elements 11′ during their operations is quickly transferred by the thermally conductive material 30 to the heat dissipating fins 221 for heat dissipation.

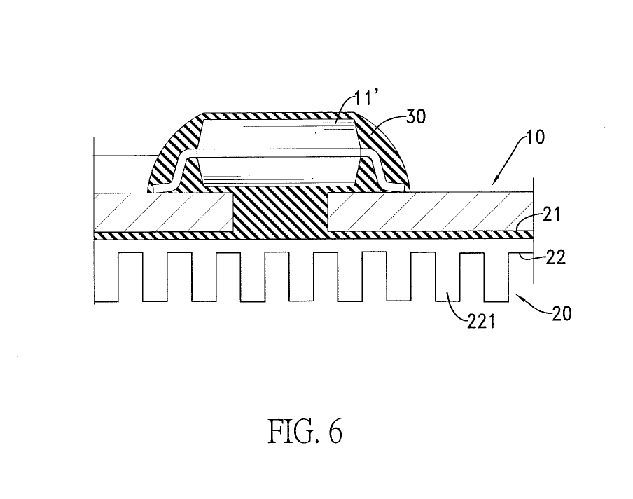

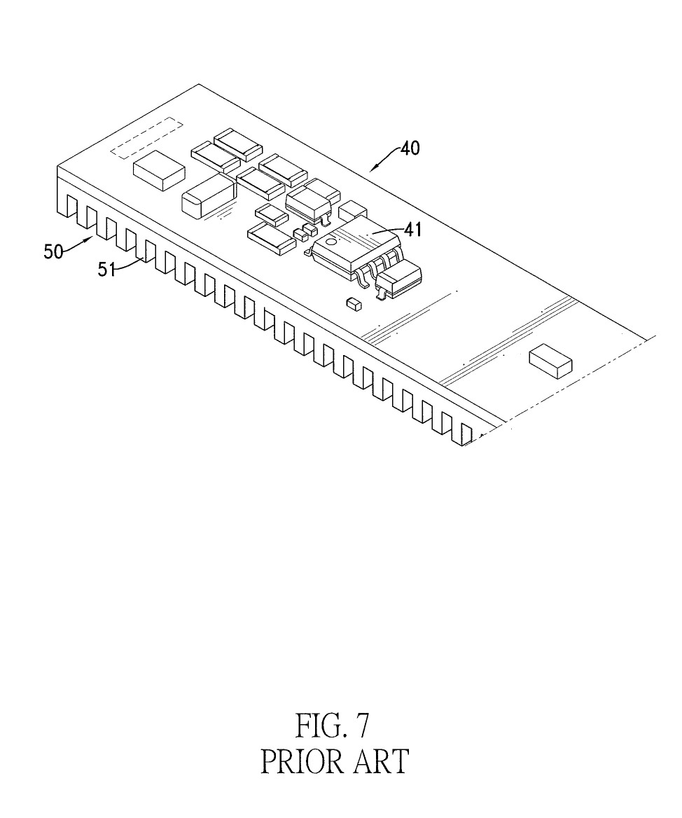

FIG. 6 shows the PCB 10 according to a second embodiment of the invention. Its structure is largely same as the first embodiment, except that the thermally conductive material 30 is also poured on the heat-generating electronic element 11′ so that the thermally conductive material 30 completely encloses the heating electronic element 11′. In addition to the advantages of the first embodiment, the thermally conductive material 30 of the second embodiment also serves as an electrical insulator to protect the heat-generating electronic element 11′, preventing short circuits between the heat-generating electronic element 11′ and another electronic element 11 or the heat dissipating device 20 and thus preventing damages to the PCB 10.

In summary, the disclosed heat dissipating PCB set utilizes the thermally conductive material to improve the thermal conductivity between the electronic elements and the heat dissipating device. Waste heat produced by the heated electronic elements is transferred by the thermally conductive materials with high thermal conductivity to the heat dissipating device for heat dissipation.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A printed circuit board (PCB) set having high-efficiency heat dissipation, the PCB set comprising:
a printed circuit board (PCB) comprising:
a top surface and a bottom surface;
a plurality of electronic elements disposed on the top surface of the PCB,
at least one heat dissipating hole formed through the top and bottom surfaces of the PCB to align with one of the electronic elements; and
at least one thermally conductive material accommodated in the at least one heat dissipating hole to contact the electronic element that aligns with the at least one heat dissipating hole; and
a heat dissipating device attached to the bottom surface of the PCB and in contact with the at least one thermally conductive material.

2. The PCB set as claimed in claim 1, wherein the thermally conductive material is an electrical insulator.

3. The PCB set as claimed in claim 2, wherein the thermally conductive material completely encloses the electronic elements.

4. The PCB set as claimed in claim 1, wherein the thermally conductive material is thermally conductive silicone.

5. The PCB set as claimed in claim 2, wherein the thermally conductive material is thermally conductive silicone.

6. The PCB set as claimed in claim 3, wherein the thermally conductive material is thermally conductive silicone.

7. The PCB set as claimed in claim 1, wherein the thermally conductive material is epoxy resin.

8. The PCB set as claimed in claim 2, wherein the thermally conductive material is epoxy resin.

9. The PCB set as claimed in claim 3, wherein the thermally conductive material is epoxy resin.

10. The PCB set as claimed in claim 1, wherein the thermally conductive material is rubber.

11. The PCB set as claimed in claim 2, wherein the thermally conductive material is rubber.

12. The PCB set as claimed in claim 3, wherein the thermally conductive material is rubber.

13. The PCB set as claimed in claim 1, wherein the heat dissipating device is made of a metal and has a thermally conductive surface and a heat dissipating surface, with the thermally conductive surface attached to the bottom surface of the PCB and in contact with the thermally conductive material and the heat dissipating surface extending downward to form a plurality of heat dissipating fins.

14. The PCB set as claimed in claim 2, wherein the heat dissipating device is made of a metal and has a thermally conductive surface and a heat dissipating surface, with the thermally conductive surface attached to the bottom surface of the PCB and in contact with the thermally conductive material and the heat dissipating surface extending downward to form a plurality of heat dissipating fins.

15. The PCB set as claimed in claim 3, wherein the heat dissipating device is made of a metal and has a thermally conductive surface and a heat dissipating surface, with the thermally conductive surface attached to the bottom surface of the PCB and in contact with the thermally conductive material and the heat dissipating surface extending downward to form a plurality of heat dissipating fins.

16. The PCB set as claimed in claim 1, wherein the electronic elements are processors, transistors, resistors, capacitors, or light-emitting diodes.

17. The PCB set as claimed in claim 2, wherein the electronic elements are processors, transistors, resistors, capacitors, or light-emitting diodes.

18. The PCB set as claimed in claim 3, wherein the electronic elements are processors, transistors, resistors, capacitors, or light-emitting diodes.
